(19) United States
(12) Patent Application Publication
(10) Pub. No.: US 2008/0261389 A1
(43) Pub. Date: Oct. 23, 2008

(54) METHOD OF FORMING MICRO PATTERN OF SEMICONDUCTOR DEVICE

(75) Inventor: Woo Yung Jung, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/962,101

(22) Filed: Dec. 21, 2007

(30) Foreign Application Priority Data
Apr. 20, 2007 (KR) 2007-38748

(51) Int. Cl. H01L 21/28; H01L 21/311

(52) U.S. Cl. 438/593; 438/703; 257/E21.257; 257/E21.179

(57) ABSTRACT

A method of forming a micro pattern of a semiconductor device method includes forming an etch target layer over a substrate, a hard mask layer over the etch target layer, and first auxiliary patterns over the etch target layer. The first auxiliary patterns defining a plurality of structures that are spaced apart from each other. Silicon is injected into the first auxiliary patterns to form silylated first auxiliary patterns. An insulating layer is formed over the hard mask layer and the silylated first auxiliary patterns, the insulating layer defining a space between two adjacent silylated first auxiliary patterns. A second auxiliary pattern is formed over the insulating layer at the space defined between the two silylated first auxiliary patterns. The insulating layer is etched to remove a portion of the insulating layer provided between the silylated first auxiliary patterns and the second auxiliary pattern while not removing a portion of the insulating layer provided below the second auxiliary pattern. The hard mask layer etched using the silylated first auxiliary patterns and the second auxiliary pattern as an etch mask to define hard mask patterns. The etch target layer is etched using the hard mask patterns to obtain target micro patterns.

### CROSS-REFERENCES TO RELATED APPLICATIONS

The present application claims priority to Korean patent application number 10-2007-038748, filed on Apr. 20, 2007, which is incorporated by reference in its entirety.

### BACKGROUND OF THE INVENTION

The present invention relates to a semiconductor device and, more particularly, to a method of forming a micro pattern in a semiconductor device, in which smaller than the resolution of a photolithography process.

As the level of integration of semiconductor devices increases, the size of a minimum line width gradually shrinks. However, the development of exposure equipment for implementing a required micro line width has not been able to keep up with the demand for higher integration. In particular, in the case where a photoresist pattern containing silicon (Si) is formed by performing a conventional exposure and development process using a photoresist film containing silicon (Si), there is a limit to the resolution capability of the exposure equipment.

Further, in order to implement a micro line width required due to the higher integration of devices, several process steps are necessary. More specifically, in order to form a hard mask pattern for forming a micro pattern, a mask formation process, a Double Exposure Etch Tech (DEET) method, a spacer formation process and/or the like, which are comprised of several steps, have to be performed. This process method not only increases overall process steps, but also increases the cost for mass produced devices.

### BRIEF SUMMARY OF THE INVENTION

The present invention is directed towards a method of forming a micro pattern of a semiconductor device, in which it can form more micro patterns than resolutions of an exposure process using reduced process steps, saving the cost for mass production of devices.

According to a first embodiment of the present invention, there is provided a method of forming a micro pattern of a semiconductor device, including forming an etch target layer, a hard mask layer, and first auxiliary patterns over a semiconductor substrate, forming silylated first auxiliary patterns by performing a silylation process on the first auxiliary patterns, forming an insulating layer on the hard mask layer including the silylated first auxiliary patterns, forming second auxiliary patterns on the insulating layer between the silylated first auxiliary patterns, performing an etch process so that the insulating layer remains only at the bottom of the second auxiliary patterns, forming a hard mask pattern by etching the hard mask layer using an etch process employing the silylated first auxiliary patterns and the second auxiliary patterns as an etch mask, and etching the etch target layer using the hard mask pattern.

The etch target layer may have a film quality of an insulating layer, a conductive layer or an interlayer insulating layer. The hard mask layer may have a stack structure of a carbon layer and a Bottom Anti-Reflective Coating (BARC) containing silicon (Si). The hard mask layer may have a stack structure of an amorphous carbon layer and a SiON layer. The carbon layer may be formed using a spin coating method. The first auxiliary patterns may have a pitch, which is twice a pitch of a target micro pattern.

The silylation process may include a process of implanting a silicon (Si) source into the first auxiliary patterns. The silylation process may be performed using a Hexa Tetra Methyl Disilazane (HMDS) gas. The silylation process may be performed in a temperature range of 100 to 140 degrees Celsius for 30 seconds to 1 hour.

The insulating layer may be formed of a carbon layer. The carbon layer may be formed using a Chemical Vapor Deposition (CVD) or spin coating method. The insulating layer may be made of a material having an etch selectivity different from that of the silylated first auxiliary patterns and the second auxiliary patterns. The second auxiliary patterns may be formed of a photoresist film containing silicon (Si). The insulating layer may be removed using a dry etch process employing O₂ plasma. During the etch process of the insulating layer, the second auxiliary patterns may remain lower in height than the silylated first auxiliary patterns. The etch process of the hard mask layer may be performed using a dry etch process.

According to a second embodiment of the present invention, there is provided a method of forming a micro pattern of a semiconductor device, including forming an etch target layer, a hard mask layer, and first auxiliary patterns over a semiconductor substrate in which a cell gate region, a select transistor region, and a peri region are defined, forming silylated first auxiliary patterns by performing a silylation process on the first auxiliary patterns, forming an insulating layer on the hard mask layer including the silylated first auxiliary patterns, forming a second auxiliary layer on the insulating layer between the silylated first auxiliary patterns formed in the cell gate region, performing a first etch process in such a manner that the second auxiliary layer formed in the cell gate region remains on the insulating layer between the silylated first auxiliary patterns and thus becomes second auxiliary patterns, removing the insulating layer on the silylated first auxiliary patterns and between the silylated first auxiliary patterns and the second auxiliary patterns in the cell gate region, forming a hard mask pattern by etching the hard mask layer using a second etch process employing the silylated first auxiliary patterns and the second auxiliary patterns as an etch mask, and etching the etch target layer using a third etch process employing the hard mask pattern as an etch mask.

The etch target layer may be formed of a tungsten silicide (WSix) layer. A stack structure of a tunnel insulating layer, a first conductive layer for a floating gate, a dielectric layer, and a second conductive layer for a control gate may be formed between the etch target layer and the semiconductor substrate. The hard mask layer may have a stack structure of a carbon layer and a BARC containing silicon (Si). The hard mask layer may have a stack structure of an amorphous carbon layer and a SiON layer. The carbon layer may be formed using a spin coating method. The first auxiliary patterns may have a pitch, which is twice a pitch of a target micro pattern.

The silylation process may include a process of implanting a silicon (Si) source into the first auxiliary patterns. The silylation process may be performed using a HMDS gas. The silylation process may be performed in a temperature range of 100 to 140 degrees Celsius for 30 seconds to 1 hour.

The insulating layer may be formed of a carbon layer. The carbon layer may be formed using a CVD or spin coating method. The insulating layer may be made of a material having an etch selectivity different from that of the silylated first auxiliary patterns and the second auxiliary patterns. The second auxiliary patterns may be formed of a photoresist film containing silicon (Si).

In the etch process of the second auxiliary layer formed in the cell gate region, part of the exposed insulating layer in the select transistor region and the peri region may also be removed. The insulating layer may be removed using a dry etch process employing O₂ plasma. During the etch process of the insulating layer, the second auxiliary patterns may remain lower in height than the silylated first auxiliary patterns.

At the time of the removal process of the insulating layer formed in the cell gate region, the insulating layer remaining in the select transistor region and the peri region may also be removed. The second etch process may be performed using a dry etch process. At the time of the third etch process, the tunnel insulating layer, the first conductive layer for a floating gate, the dielectric layer, and the second conductive layer for a control gate formed between the etch target layer and the semiconductor substrate may also be etched, thus forming a gate.

### BRIEF DESCRIPTION OF THE DRAWINGS

FIGS. 1A to 1I are sectional views illustrating a method of forming a micro pattern of a semiconductor device according to a first embodiment of the present invention; and

FIGS. 2A to 2J are sectional views illustrating a method of forming a micro pattern of a semiconductor device according to a second embodiment of the present invention.

### DESCRIPTION OF SPECIFIC EMBODIMENTS

Specific embodiments according to the present invention will be described with reference to the accompanying drawings.

A semiconductor device according to a first embodiment of the present invention is described below.

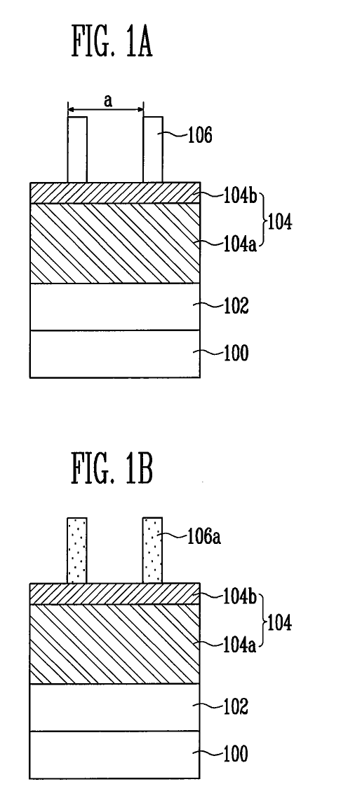

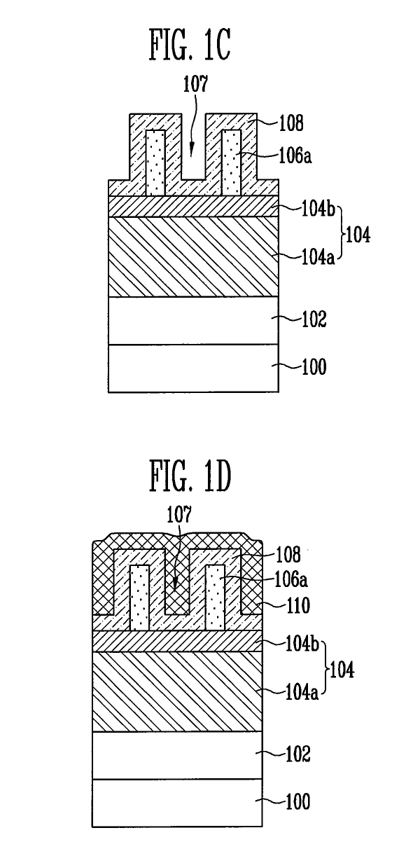

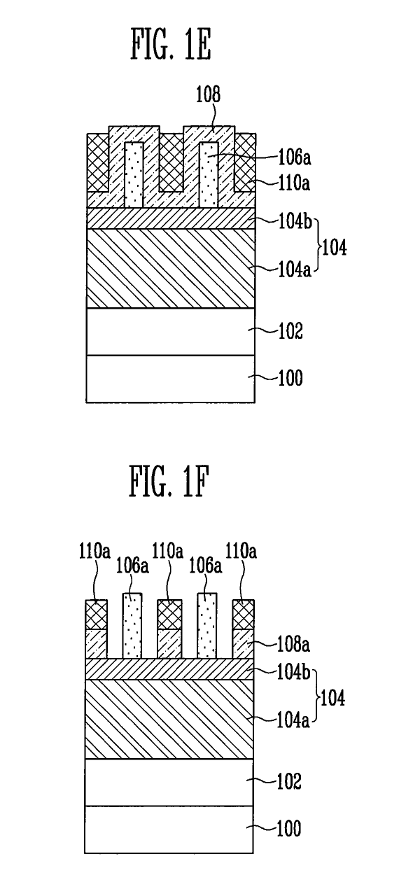

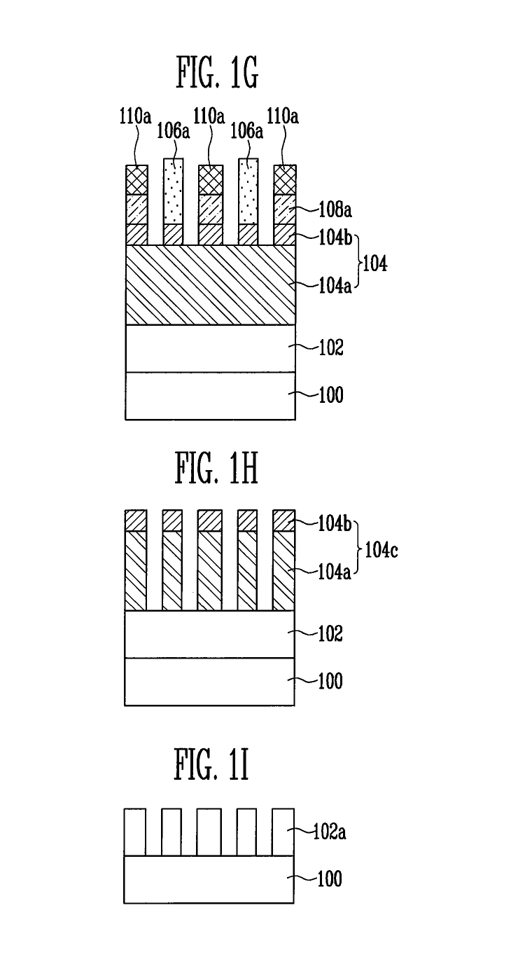

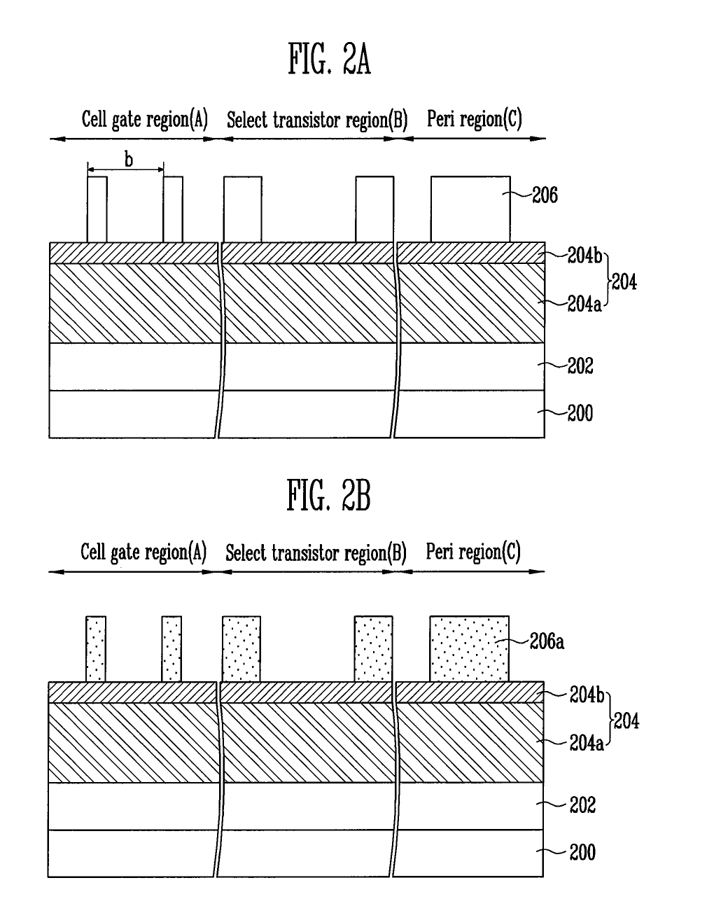

Referring to FIG. 1A, an etch target layer 102 is formed over a semiconductor substrate 100. The etch target layer 102 may be any layer that requires a micro pattern (e.g., an insulating layer, a conductive layer, an interlayer insulating layer, etc.) A hard mask layer 104 is formed on the etch target layer 102. The hard mask layer 104 may have a stack structure of a carbon layer 104a formed using a spin coating method and a Bottom Anti-Reflective Coating (BARC) 104b containing silicon (Si), or a stack structure of an amorphous carbon layer 104a and a silicon oxynitride (SiON) layer 104b.

First auxiliary patterns 106 are formed on the hard mask layer 104. The first auxiliary patterns 106 may be made of a photoresist film. The first auxiliary patterns 106 may have a pitch “a”, which is twice the pitch of a target micro pattern. This is because second auxiliary patterns are formed between the first auxiliary patterns 106 in a subsequent process.

Referring to FIG. 1B, silicon is implanted (or incorporated or diffused) into the first auxiliary patterns using a silylation process to form silylated first auxiliary patterns 106a. The silylation process may be performed using a Hexa Tetra Methyl Disilazane (HMDS) gas as a silicon source in a temperature range of 100 to 140 degrees Celsius for 30 seconds to 1 hour. In such a process, the HMDS is diffused into the first auxiliary patterns 106a. At this time, if a silylation process is performed after a photoresist pattern is formed instead of forming a pattern by etching a silylated photoresist film, a resolution higher than that of the existing exposure process can be formed.

Thus, if the silylated first auxiliary patterns 106a are formed by performing the silylation process on the first auxiliary patterns instead of forming the first auxiliary patterns using the silylated first auxiliary layers through an exposure and development process, more micro patterns than resolutions can be obtained.

Referring to FIG. 1C, an insulating layer 108 is formed on a top surface of the hard mask layer 104 and the silylated first auxiliary patterns 106a. The insulating layer 108 may be made of a carbon layer using a CVD or spin coating method. The carbon layer prevents damage to the silylated first auxiliary patterns 106a and can also be removed in a subsequent etch process because the etch selectivity (or etch characteristics) of the carbon layer is different from that of the silylated first auxiliary patterns 106a.

Thus, the insulating layer 108 may be made of a material having an etch selectivity different from that of the second auxiliary layer and the silylated first auxiliary patterns 106a. The insulating layer 108 may have a thickness, which is about half the pitch of a micro pattern that will be formed. The insulating layer 108 is formed conformal to the shape of the silylated first auxiliary patterns 106a and defines a space or trench 107 therebetween.

Referring to FIG. 1D, a second auxiliary layer 110 is formed on the insulating layer 108 in such a way to gap fill the space 107 defined between the silylated first auxiliary patterns 106a. The second auxiliary layer 110 may be made of a photoresist film containing silicon (Si). Thus, the second auxiliary layer 110 has an etch selectivity different from that of the insulating layer 108.

Referring to FIG. 1E, second auxiliary patterns 110a are formed by etching the second auxiliary layer using an etch process until a top surface of the insulating layer 108 is exposed. As a result, the second auxiliary patterns 110a are defined at the space 107 between the silylated first auxiliary patterns 106a. The etch process may be performed using an etchback process. The silylated first auxiliary patterns 106a and the second auxiliary patterns 110a are made of a material having the same etch selectivity in the present embodiment.

Referring to FIG. 1F, the exposed insulating layer is removed, i.e., the top portion of the insulating layer and the portion provided between the silylated first auxiliary patterns 106a and the second auxiliary patterns 110a are removed. The unexposed insulating layer provided below the second auxiliary patterns 110a is not removed and defines insulating patterns 108a. The insulating layer may be removed by a dry etch process employing O₂ plasma. In the etch process of the insulating layer, a top surface of the second auxiliary patterns 110a is removed partially. Accordingly, the second auxiliary patterns 110a are lower in height than the silylated first auxiliary patterns 106a.

Thus, in the etch process of the insulating layer, the silylated first auxiliary patterns 106a and the second auxiliary patterns 110a are not etched since the insulating layer has an etch selectivity different from that of the silylated first auxiliary patterns 106a and the second auxiliary patterns 110a. If the second auxiliary patterns 110a are formed between the silylated first auxiliary patterns 106a as described above, a pattern having a target pitch is formed.

Referring to FIG. 1G, the BARC 104b containing silicon (Si) of the hard mask layer 104 is removed using the silylated first auxiliary patterns 106a, the insulating patterns 108a, and the second auxiliary patterns 110a as an etch mask. The BARC 104b containing silicon (Si) may be removed using a dry etch process. In the etch process of the BARC 104b containing silicon (Si), the silylated first auxiliary patterns 106a and the second auxiliary patterns 110a are partially lost.

Referring to FIG. 1H, a hard mask pattern 104c having a desired line and space is formed by etching the carbon layer 104a of the hard mask layer using the silylated first auxiliary patterns, the insulating patterns, and the second auxiliary patterns as an etch mask. The carbon layer 104a may be removed using a dry etch process. In the formation process of the hard mask pattern 104c, the silylated first auxiliary patterns, the insulating patterns, and the second auxiliary patterns may be removed. If the silylated first auxiliary patterns, the insulating patterns, and the second auxiliary patterns partially remain, they are all removed in a subsequent process.

Referring to FIG. 1I, target patterns 102a are formed by etching the etch target layer 102 using the hard mask pattern 104c having a desired line and space as an etch mask. The hard mask pattern 104c is then removed.

As described above, the silylated first auxiliary patterns 106a are formed by performing a silylation process on the first auxiliary patterns 106 and, therefore, a micro pattern smaller than the resolution of an exposure process can be formed. Accordingly, a micro pattern having a desired Critical Dimension (CD) can be formed. Further, since the existing DEET method or spacer formation process used to form a micro pattern is not performed, process steps can be shortened. Due to this, the cost for mass produced devices can be reduced.

The present invention may be applied to a fabrication method of a NAND flash memory device as follows.

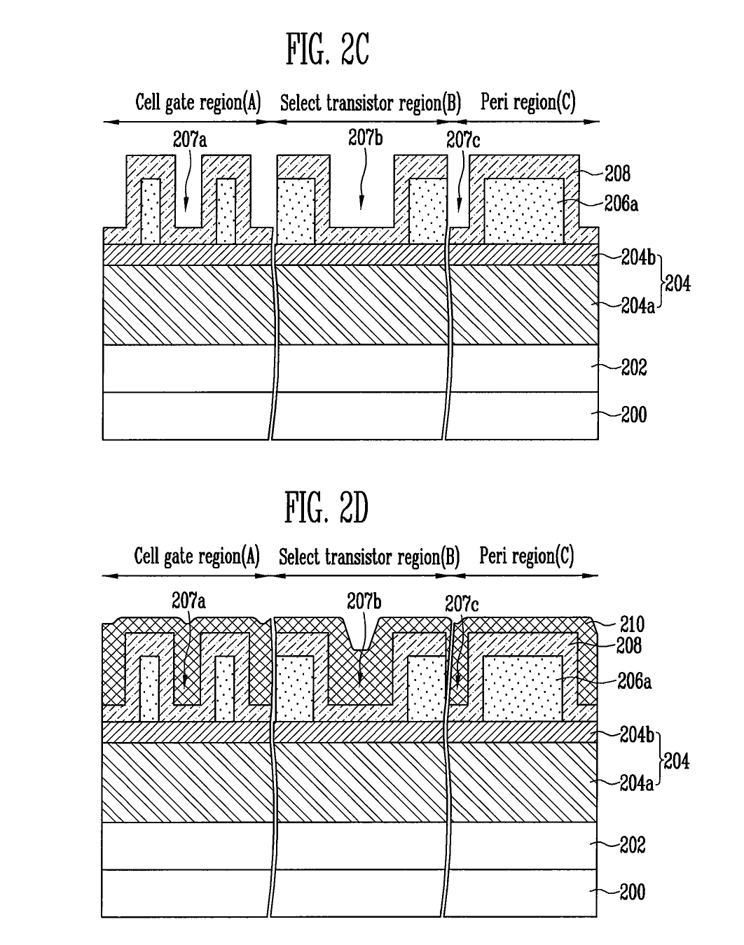

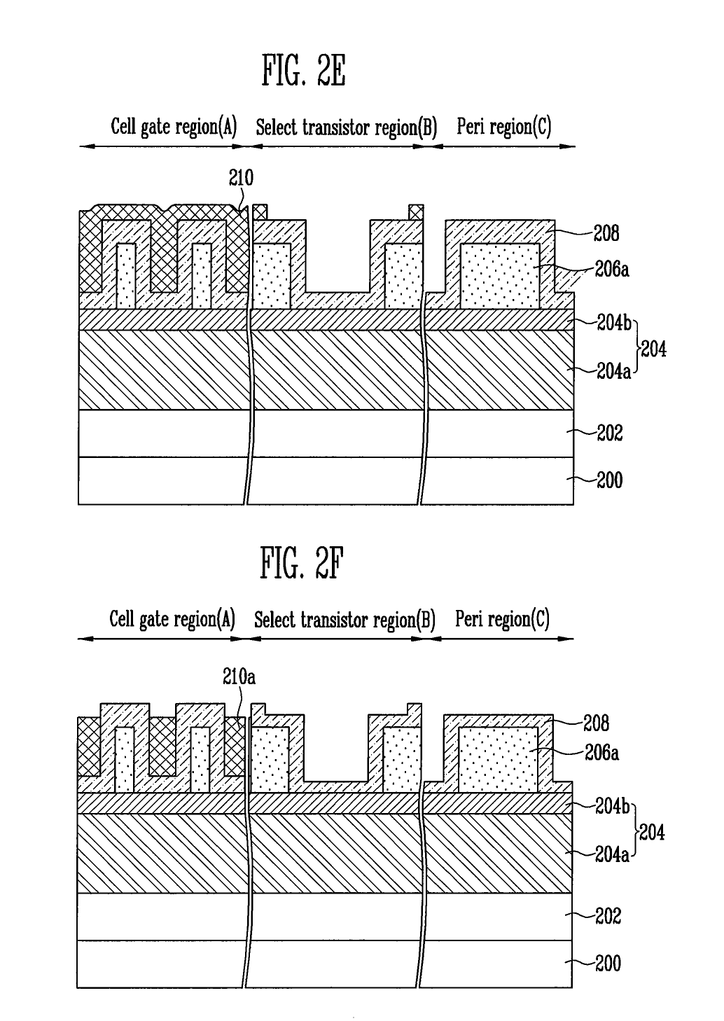

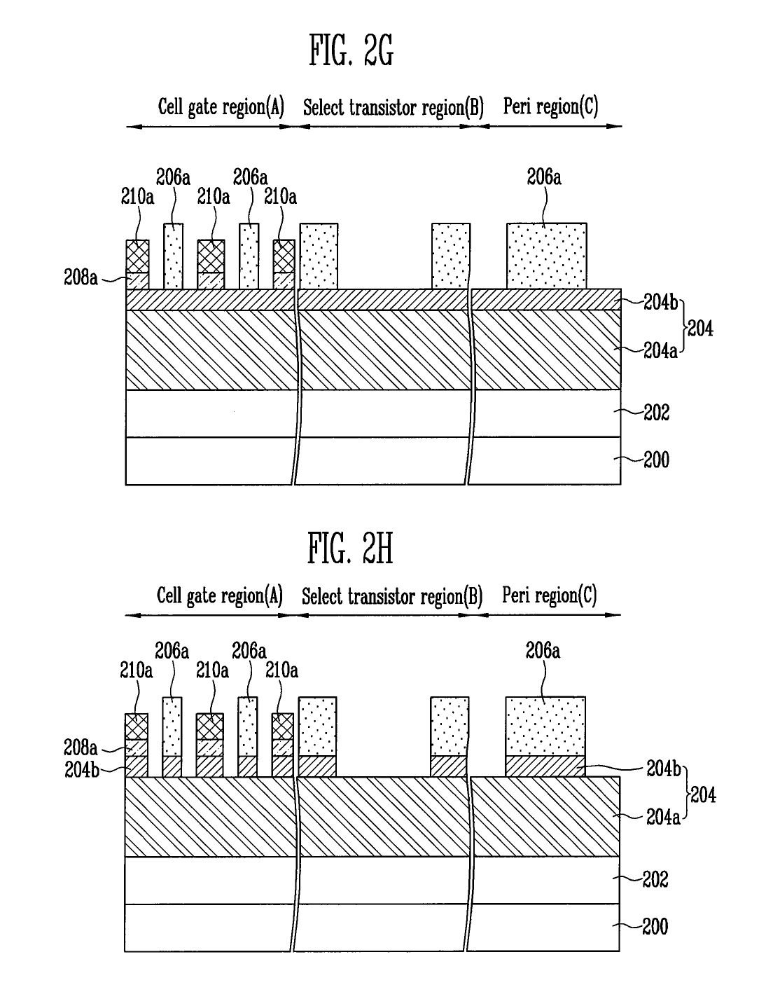

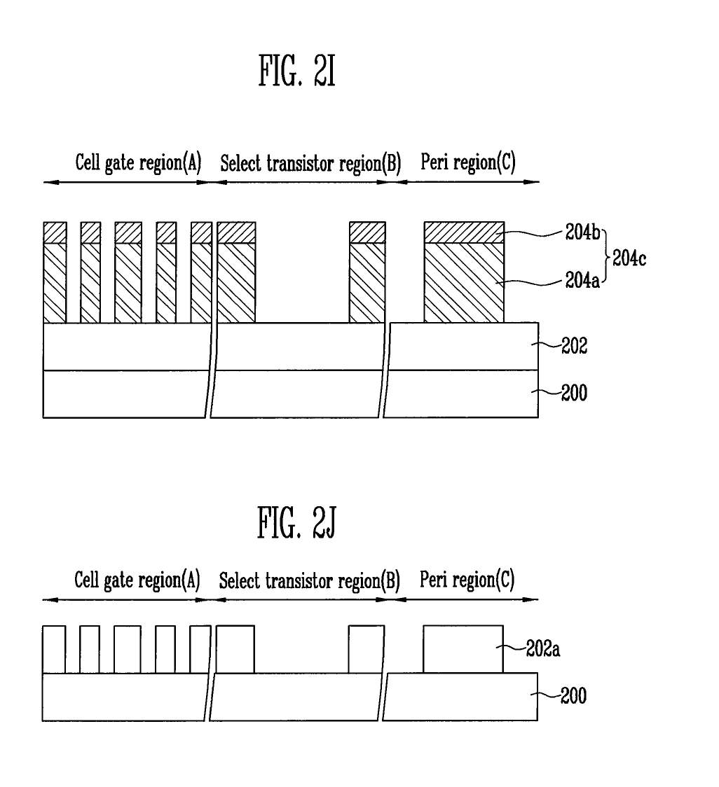

FIGS. 2A to 2J are sectional views illustrating a method of forming a micro pattern of a semiconductor device according to a second embodiment of the present invention.

Referring to FIG. 2A, an etch target layer 202 is formed over a semiconductor substrate 200 in which a cell gate region A, a select transistor region B, and a peri region C are defined. The etch target layer 202 is made of tungsten silicide (WSix), but a stack structure of a tunnel insulating layer, a first conductive layer for a floating gate, a dielectric layer, and a second conductive layer for a control gate is formed between the tungsten silicide (WSix) layer and the semiconductor substrate 200.

A hard mask layer 204 is formed on the etch target layer 202. The hard mask layer 204 may have a stack structure of a carbon layer 204a formed using a spin coating method and a BARC 204b containing silicon (Si), or a stack structure of an amorphous carbon layer 204a and a silicon oxynitride (SiON) layer 204b.

First auxiliary patterns 206 are formed on the hard mask layer 204. The first auxiliary patterns 206 may be made of a photoresist film. The first auxiliary patterns 206 may have a pitch “b”, which is greater than the pitch of a target micro pattern (e.g., twice the pitch of the target micro pattern). The desired pitch for the target micro pattern is obtained by forming second auxiliary patterns between the first auxiliary patterns 206 in a subsequent process.

Referring to FIG. 2B, a silicon (Si) source is implanted into the first auxiliary patterns using a silylation process to form silylated first auxiliary patterns 206a. The silylation process may be performed using a HMDS gas in a temperature range of 100 to 140 degrees Celsius for 30 seconds to 1 hour.

Referring to FIG. 2C, an insulating layer 208 is formed on a top surface of the hard mask layer 204 and the silylated first auxiliary patterns 206a. The insulating layer 208 may be made of a carbon layer using a CVD or spin coating method. One of the reasons for using the carbon layer as the insulating layer 208 is that it can prevent damage to the silylated first auxiliary patterns 206a. Another reason it that it has different etch characteristics than the silylated first auxiliary patterns 206a. In other embodiments, the insulating layer may not be a carbon layer.

The insulating layer 208 may be made of a material having an etch selectivity different from that of the second auxiliary layer and the silylated first auxiliary patterns 206a. The insulating layer 208 may have a thickness, which is about half the pitch of a micro pattern that will be formed. The insulating layer 208 is a formed conformal to the shape of the silylated first auxiliary patterns 206a and define first space 207a in the cell gate region, second space 207b in the select transistor region, and third space 207c in the peri region.

Referring to FIG. 2D, a second auxiliary layer 210 is formed on the insulating layer 208 in such a way to gap fill the spaces 207a, 207b, and 207c provided between the silylated first auxiliary patterns 206a. The second auxiliary layer 210 may be made of a photoresist film containing silicon (Si).

Referring to FIG. 2E, the second auxiliary layer 210 formed in the select transistor region B and the peri region C is removed using an exposure and development process, thus forming a pattern in which the second auxiliary layer 210 remains only in the cell gate region A. One reason for leaving the second auxiliary layer 210 only in the cell gate region A is that it is not necessary to form a micro pattern in the select transistor region B and the peri region C. At this time, if the second auxiliary layer 210 is formed using a photoresist film containing silicon (Si) not a general insulating material and mask exposure and development processes are then sequentially performed, an additional etch process need not to be performed because the photoresist film containing silicon (Si) formed in the select transistor region B and the peri region C is removed. Consequently, the process steps can be reduced since the etch process is not implemented.

Referring to FIG. 2F, second auxiliary patterns 210a are formed in the cell gate region A by etching the second auxiliary layer formed in the cell gate region A until a top surface of the insulating layer 208 is exposed using an etch process. The etch process may be performed using an etchback process. During the etch process of the second auxiliary layer formed in the cell gate region A, the exposed insulating layer 208 of the select transistor region B and the peri region C is partially removed. The silylated first auxiliary patterns 206a and the second auxiliary patterns 210a are made of a material having the same etch selectivity in the present embodiment.

Referring to FIG. 2G, the exposed insulating layer is removed, i.e., the top portion of the insulating layer and the portion provided between the silylated first auxiliary patterns 206a and the second auxiliary patterns 210a are removed. The unexposed insulating layer provided below the second auxiliary patterns 210a is not removed and defines insulating patterns 208a. The insulating layer may be removed by a dry etch process employing O₂ plasma. In the etch process of the insulating layer, a top surface of the second auxiliary patterns 210a may be lost partially. Accordingly, the second auxiliary patterns 210a remain lower in height than the silylated first auxiliary patterns 206a. When the insulating layer formed in the cell gate region A is removed, the insulating layer 208 remaining in the select transistor region B and the peri region C is also removed.

Thus, at the time of the etch process of the insulating layer, the silylated first auxiliary patterns 206a and the second auxiliary patterns 210a are not etched since the insulating layer has an etch selectivity different from that of the silylated first auxiliary patterns 206a and the second auxiliary patterns 210a. If the second auxiliary patterns 210a are formed between the silylated first auxiliary patterns 206a and the silylated first auxiliary patterns 206a as described above, a pattern having a target pitch is formed.

Referring to FIG. 2H, the BARC 204b containing silicon (Si) of the hard mask layer 204 is removed using the silylated first auxiliary patterns 206a, the insulating patterns 208a, and the second auxiliary patterns 210a as an etch mask. The BARC 204b containing silicon (Si) may be removed using a dry etch process. In the etch process of the BARC 204b containing silicon (Si), the silylated first auxiliary patterns 206a and the second auxiliary patterns 210a are partially lost.

Referring to FIG. 2I, a hard mask pattern 204c having a desired line and space is formed by etching the carbon layer 204a of the hard mask layer using the silylated first auxiliary patterns, the insulating patterns, and the second auxiliary patterns as an etch mask. The carbon layer 204a may be removed using a dry etch process. In the formation process of the hard mask pattern 204c, the silylated first auxiliary patterns, the insulating patterns, and the second auxiliary patterns may be removed. If the silylated first auxiliary patterns, the insulating patterns, and the second auxiliary patterns partially remain, they are all removed in a subsequent process.

Referring to FIG. 2J, target patterns 202a are formed by etching the etch target layer 202 using the hard mask pattern 204c having a desired line and space as an etch mask. The hard mask pattern 204c is then removed.

As described above, the silylated first auxiliary patterns 206a are formed by performing a silylation process on the first auxiliary patterns 206 and, therefore, a micro pattern with a resolution higher than that of an exposure process can be formed. Accordingly, a micro pattern having a desired CD can be formed.

Further, since the existing DEET method or spacer formation process used to form a micro pattern is not performed, process steps can be shortened. Due to this, the cost for mass produced devices can be reduced.

The present invention can be applied to not only a fabrication method of NAND flash memory devices, but also a fabrication method of NOR flash memory devices. Alternatively, the present invention can also be applied to a pattern having a line and space of a DRAM and a contact array pattern.

The present invention is not limited to the disclosed embodiments, but may be implemented in various manners. The embodiments are provided to complete the disclosure of the present invention and to allow those having ordinary skill in the art to understand the scope of the present invention. The present invention is defined by the category of the claims.

What is claimed is:

1. A method of forming a micro pattern of a semiconductor device method, the method comprising:
forming an etch target layer over a substrate, a hard mask layer over the etch target layer, and first auxiliary patterns over the etch target layer, the first auxiliary patterns defining a plurality of structures that are spaced apart from each other;
injecting silicon into the first auxiliary patterns to form silylated first auxiliary patterns;
forming an insulating layer over the hard mask layer and the silylated first auxiliary patterns, the insulating layer defining a space between two adjacent silylated first auxiliary patterns;
forming a second auxiliary pattern over the insulating layer at the space defined between the two silylated first auxiliary patterns;
etching the insulating layer to remove a portion of the insulating layer provided between the silylated first auxiliary patterns and the second auxiliary pattern while not removing a portion of the insulating layer provided below the second auxiliary pattern;
etching the hard mask layer using the silylated first auxiliary patterns and the second auxiliary pattern as an etch mask to define hard mask patterns; and
etching the etch target layer using the hard mask patterns to obtain target micro patterns.

2. The method of claim 1, wherein the etch target layer is an insulating layer, a conductive layer or an interlayer insulating layer.

3. The method of claim 1, wherein the hard mask layer includes a carbon layer and a Bottom Anti-Reflective Coating (BARC) containing silicon (Si).

4. The method of claim 3, wherein the carbon layer is formed using a spin coating method.

5. The method of claim 1, wherein the hard mask layer includes an amorphous carbon layer and a SION layer.

6. The method of claim 1, wherein the first auxiliary patterns have a pitch that is twice a pitch of the target micro patterns.

7. The method of claim 1, wherein the silylation process includes a process of injecting silicon into the first auxiliary patterns.

8. The method of claim 1, wherein the silylation process is performed using a Hexa Tetra Methyl Disilazane (HMDS) gas, wherein the silicon is injected into the first auxiliary patterns by diffusing the HMDS into the first auxiliary patterns.

9. The method of claim 1, wherein the silylation process is performed in a temperature range of 100 to 140 degrees Celsius for 30 seconds to 1 hour.

10. The method of claim 1, wherein the insulating layer is formed of a carbon layer.

11. The method of claim 10, wherein the carbon layer is formed using a Chemical Vapor Deposition (CVD) or spin coating method.

12. The method of claim 1, wherein the insulating layer is made of a material having an etch selectivity different from that of the silylated first auxiliary patterns and the second auxiliary patterns.

13. The method of claim 1, wherein the second auxiliary patterns are formed of a photoresist film containing silicon (Si).

14. The method of claim 1, wherein the insulating layer is removed using a dry etch process employing O₂ plasma.

15. The method of claim 1, wherein during the etch process of the insulating layer, the second auxiliary patterns is made lower in height than the silylated first auxiliary patterns.

16. The method of claim 1, wherein forming the second auxiliary pattern over the insulating layer includes:
forming an auxiliary layer over the insulating layer and filling the space defined between the two silylated first auxiliary patterns;
and etching the auxiliary layer until a top surface of the insulating layer is exposed.

17. A method of forming a micro pattern of a semiconductor device, the method comprising:
forming an etch target layer over a substrate defining a cell gate region, a select transistor region, and a peri region, a hard mask layer over the etch target layer, and first auxiliary structures over the hard mask layer;
forming silylated first auxiliary structures by performing a silylation process on the first auxiliary structures;
forming an insulating layer over the hard mask layer including the silylated first auxiliary structures;
forming a second auxiliary layer over the insulating layer and between the silylated first auxiliary structures formed in the cell gate region;
performing a first etch process in such a manner that the second auxiliary layer formed in the cell gate region remains on the insulating layer between the silylated first auxiliary structures and thus becomes second auxiliary structures;
removing a portion of the insulating layer provided directly over the silylated first auxiliary structures and a portion of the insulating layer provided between the silylated first auxiliary structures and the second auxiliary structures in the cell gate region;
forming a hard mask structures by etching the hard mask layer using a second etch process employing the silylated first auxiliary structures and the second auxiliary structures as an etch mask; and
etching the etch target layer using a third etch process employing the hard mask structures as an etch mask to obtain target micro structures.

18. The method of claim 17, wherein the etch target layer is formed of a tungsten silicide (WSix) layer.

19. The method of claim 17, wherein a stack structure of a tunnel insulating layer, a first conductive layer for a floating gate, a dielectric layer, and a second conductive layer for a control gate is formed between the etch target layer and the semiconductor substrate.

20. The method of claim 19, wherein at the time of the third etch process, the tunnel insulating layer, the first conductive layer for a floating gate, the dielectric layer, and the second conductive layer for a control gate formed between the etch target layer and the semiconductor substrate are also etched, thus forming a gate structure.

21. The method of claim 17, wherein the hard mask layer includes a carbon layer and a BARC containing silicon (Si).

22. The method of claim 20, wherein the carbon layer is formed using a spin coating method.

23. The method of claim 17, wherein the hard mask layer includes an amorphous carbon layer and a SiON layer.

24. The method of claim 17, wherein the first auxiliary structures have a pitch that is twice that of the target micro structures.

25. The method of claim 17, wherein the silylation process includes a process of diffusing a silicon (Si) source into the first auxiliary structures.

26. The method of claim 17, wherein the silylation process is performed using a HMDS gas.

27. The method of claim 17, wherein the silylation process is performed in a temperature range of 100 to 140 degrees Celsius for 30 seconds to 1 hour.

28. The method of claim 17, wherein the insulating layer is formed of a carbon layer.

29. The method of claim 28, wherein the carbon layer is formed using a CVD or spin coating method.

30. The method of claim 17, wherein the insulating layer is made of a material having an etch selectivity different from that of the silylated first auxiliary structures and the second auxiliary structures.

31. The method of claim 17, wherein the second auxiliary structures are formed of a photoresist film containing silicon (Si).

32. The method of claim 17, wherein in the etch process of the second auxiliary layer formed in the cell gate region, part of the exposed insulating layer in the select transistor region and the peri region is also removed.

33. The method of claim 17, wherein the insulating layer is removed using a dry etch process employing O₂ plasma.

34. The method of claim 17, wherein during the etch process of the insulating layer, the second auxiliary structures is made lower in height than the silylated first auxiliary structures.

35. The method of claim 17, wherein at the time of the removal process of the insulating layer formed in the cell gate region, the insulating layer remaining in the select transistor region and the peri region is removed.

36. The method of claim 17, wherein the second etch process is performed using a dry etch process.
